(19) United States
(12) Patent Application Publication
(10) Pub. No.: US 2011/0030789 A1
(43) Pub. Date: Feb. 10, 2011

(54) AIR STABLE PHOTOVOLTAIC DEVICE

(75) Inventor: Frederik Christian Krebs, Kgs. Lyngby (DK)

Correspondence Address: PILLSBURY WINTHROP SHAW PITTMAN, LLP, P.O. BOX 10500, MCLEAN, VA, 22102, US

(73) Assignee: THE TECHNICAL UNIVERSITY OF DENMARK, Kgs. Lyngby (DK)

(21) Appl. No.: 12/918,282

(22) PCT Filed: Feb. 17, 2009
(86) PCT No.: PCT/EP2009/051865

§ 371 Date: Oct. 21, 2010

(30) Foreign Application Priority Data
Feb. 18, 2008 (GB) 0802934.0

(51) Int. Cl. H01L 31/0296; H01L 31/18; C08F 228/06

(52) U.S. Cl. 136/258; 438/85; 526/256; 257/E31.015

(57) ABSTRACT

A method of forming a conducting polymer based photovoltaic device including: (a) providing a transparent first electrode; (b) providing the transparent first electrode with a layer of metal oxide nanoparticles, wherein the metal oxide is selected from the group consisting of: TiO₂, TiOₓ, and ZnO; (c) providing the layer of metal oxide nanoparticles with a bulk hetero junction layer including metal oxide nanoparticles and a hole conducting polymer containing thermocleavable groups, wherein the metal oxide is selected from the group consisting of: TiO₂, TiOₓ, CeO₂, Nb₂O₅ and ZnO; (d) heating the bulk heterojunction layer, to cleave the thermally cleavable groups to produce an insoluble hole containing polymer; (e) providing the bulk heterojunction layer with a hole transporting layer; and (f) providing the hole transporting layer with a second electrode. Also a conducting polymer based photovoltaic device, and polymeric compounds suitable for use in such devices and methods.

The present invention relates to an air stable photovoltaic device, a method of forming an air stable photovoltaic device, and to an assembly including such a device. Photovoltaic devices inter-convert light and electricity.

Solar power is an important renewable energy source, and can be harvested using photovoltaic cells (solar cells). Renewable energy sources are desirable for a number of reasons. First, such energy sources enable a reduction in consumption of non-renewable energy sources. Second, such energy sources enable the use of electrical devices without the need for a mains power source. This is of particular interest in remote locations, for example at sea or in developing countries.

In solar cells, photons are absorbed and the energy of the photon forms an exciton consisting of an electron and a hole which initially are bound together. These can be separated into free charge carriers and caused to migrate towards respective electrodes by an electric field, suitably produced by electrodes of differing work functions. Cells containing two components (heterojunction cells) can give much higher efficiency than cells containing a single component because of increased charge separation at the interface between the two components.

In electroluminescent devices, which can also be photovoltaic devices, electrons and holes injected at opposed electrodes reach one another by conduction and recombine to produce light.

Solar cells may rely on photovoltaic polymers. It has been recognised that potentially such devices have advantages over the conventional, similar devices based on inorganic semiconductors. These potential advantages include cheapness of the materials and versatility of processing methods, flexibility (lack of rigidity) and toughness. In particular, there is the potential advantage of high volume production at low unit cost.

Photovoltaic polymers can be derived from chemically doped conjugated polymers, for example partially oxidised (p-doped) polypyrrole. The article ‘Conjugated polymers: New materials for photovoltaics’, Wallace et al, Chemical Innovation, April 2000, Vol. 30, No. 1, 14-22 reviews the field.

Previously known polymer and organic solar cells have suffered from the disadvantage of short lifetime. The half-lives of such solar cells have been measured in minutes, hours or days rather than weeks or months.

The present inventors have appreciated that, in order to produce polymer solar cells on a commercial basis, there are three criteria that must be met by such cells. These are: (1) high power conversion efficiency; (2) long-term stability; and (3) large area processing, i.e. the ability to make large cells or combinations of cells.

There are polymer solar cells known in the art that are capable of meeting these criteria individually [see, for example, Li et al (Nature Mat. 4 (2005) pp 864), Ma et al. (Adv Funct. Mater. 15 (2005) pp 1617), Kim et al. (Science 317 (2007) pp 222), Krebs and Spanggaard (Chem. Mater. 17 (2005) pp 5235), Krebs and Norrman (Prog. Photovolt. Res. Appl. 15 (2007) pp 697), Yang et al. (Nanolett. 5 (2005) pp 579), Katz et al. (Eur. Phys. J. Appl. Phys 36 (2007) pp 307-311), Krebs et al. (Sol. Energy Mater. Sol. Cells 83 (2004) pp 293), Krebs et al (Mater. Sci. En. B 138 (2007) pp 106), Dennler et al (J. Mater. Res. 20 (2005) pp 3224-3233), and Lungenschmied et al. (Sol. En. Mater. Sol. Cells 91 (2007) pp 379-384)]. If a polymer solar cell can be manufactured such that it meets any two of these criteria, then these may be suitable for applications in a specific limited field.

It is an aim, in view of the capacity and lifetime of the polymer solar cells known at present, to improve such polymer solar cells in order that they may compete with known conventional batteries. This introduces the particular requirement that a polymer solar cell must be stable in the absence of light for a significant length of time under ambient conditions before it is intended for use, in order that special storage conditions are not required. There is one example of a device having the required long-term dark storage stability known to the inventors (Lungenschmied et al., Sol. En. Mater. Sol. Cells 91 (2007) 379-384), which device uses encapsulation of the functional layers to exclude the ambient atmosphere and prevent degradation. The factors affecting the dark stability of certain polymer solar cells have previously been studied (Jeranko et al., Sol. En. Mater. Sol. Cells 83 (2004) pp 247).

Fréchet et al. (WO2005/107047) have disclosed polymer solar cells containing a layer of metal oxide and a layer of thermocleavable polythiophene.

Risø National Laboratory (GB2424512) has disclosed the use of a thermocleavable polythiophene layer and a fullerene layer in polymer solar cells.

It is universally accepted that such cells require protection from the ambient atmosphere (in particular from oxygen and humidity/water) in order to operate. Thus, one would not expose a prior art solar cell to light and attempt to draw power from it without first encapsulating it in a material that prevents oxygen and humidity/water reaching the active layers of the device.

Examples of encapsulation methods known in the art are discussed in Krebs (Sol. En. Mater. Sol. Cells 90 (2006) pp 3633-3643) and Dennler et al. (Thin Solid Films 511-512 (2006) pp 349-353). Sealing the polymer solar cell into a glass ampoule, sealing it between a milled aluminium plate and a glass plate using glass fibre containing prepreg, or using plasma vapour deposition to deposit barrier coatings as part of the encapsulant or directly on the outside of the cell, or inclusion of getter materials inside that package that will actively absorb the oxygen and moisture that penetrate the cell until saturated thus delaying the degradation processes, are possible methods. It is clear from these documents that to encapsulate the devices is time-consuming and requires complex equipment. It is also clear that encapsulation is thought critical to protect the device from degradation due to reaction with water, even for the more stable devices discussed in Krebs using polythiophene-derived polymers in the active layer.

In order to reduce the production cost of polymer solar cells, it is necessary to exclude production steps that increase the production time or cost, such as steps that must be carried out under vacuum or inert atmosphere. Ideally, the use of protective layers not contributing directly to the functioning of the device would be reduced or excluded. In particular, the encapsulation of the device to exclude oxygen should be avoided.

It is currently usual, when forming polymer solar cells, to use two vacuum steps: one to form the transparent front electrode, usually of indium tin oxide (ITO), and one to form the metallic back electrode by vapour deposition. These steps are slow and thus expensive. This somewhat negates the inherent advantage of polymer solar cells of being able to produce the required polymer layers using solution techniques. Thus, it is an aim to produce solar cells with fewer vacuum processing steps.

In addition, ITO is an expensive component in itself: indium currently costs around 1000 $ per kg. Also, the available reserves in the earth's crust are estimated to be rather low and certainly not sufficient for large scale production of solar cells. Thus, it is an aim to avoid the use of indium-containing compounds in polymer solar cells.

In addition, the use of other expensive materials should be avoided where possible. The most efficient polymer solar cells known to date rely on fullerene derivatives as electron acceptors and electron conductors. While these materials are now available on a large scale, these are still expensive and make a significant contribution to the overall cost of the cell. It is therefore an aim to provide efficient solar cells without the need for fullerene derivatives.

The use of steps requiring very high temperatures, the use of clean rooms or glove box conditions, and complex processing steps should also be avoided where possible in order to increase the cost efficiency of polymer solar cells.

In a first aspect, the present invention relates to a method of forming a conducting polymer based photovoltaic device comprising the steps of:
(a) providing a transparent first electrode;
(b) providing a layer of metal oxide nanoparticles, wherein the metal oxide is selected from the group consisting of: TiO₂, TiOₓ, ZnO and any combination thereof;
(c) providing the layer of metal oxide nanoparticles with a bulk heterojunction layer comprising metal oxide nanoparticles and a hole conducting polymer containing thermocleavable groups, wherein the metal oxide is selected from the group consisting of: ZnO, TiO₂, TiOₓ, CeO₂, Nb₂O₅ and any combination thereof;
(d) heating the bulk heterojunction layer to cleave the thermally cleavable groups to produce an insoluble hole containing polymer;
(e) providing the bulk heterojunction layer with a hole transporting layer; and
(f) providing the hole transporting layer with a second electrode.

Preferably, the method comprises the further steps of:
(g) connecting the photovoltaic device to a power consuming device; and
(h) exposing the photovoltaic device to light;

wherein the photovoltaic device is exposed to the ambient atmosphere and is not protected from oxygen and humidity/water in use.

Suitably, steps (b), (c), (d) and (e) can be carried out in that order or in reverse order.

Preferably, the photovoltaic device is a solar cell. However, the device may also be an electroluminescent device.

Suitably, the method may comprise the performance of the group of three steps (b), (c), (d) and (e) more than once after step (a) and before step (f). Each time the group of steps (b), (c), (d) and (e) is performed, a different selection of metal oxide and of components of the bulk heterojunction layer may be made. Suitably, the selection of the metal oxide and components of the bulk heterojunction layer may alternate between two choices between each performance of each group of steps (b), (c), (d) and (e). Cells constructed in this fashion are known as tandem cells.

The advantage of tandem cells is that they may harvest more light than a single cell. Suitably, two polymers harvesting light at different wavelength ranges may be employed in the bulk heterojunction layer of each cell forming the tandem cell. For example, P3CT may be used as the hole conducting polymer in one cell and P3CTTP as the hole conducting polymer in the adjacent cell. In this case P3CT harvests light up to around 600 nm and passes all light at longer wavelengths. The P3CTTP harvests light up to about 950 nm. In principle, such cells will have a higher efficiency for this reason. In order to maximise the energy obtained, the current generated by each cell must be matched since the cells are placed in series.

It is necessary to carry out the step (d) after each time step (c) is performed and before the subsequent layer (e) is deposited. This ensures that the deposition of further layers cannot affect the integrity of the bulk heterojunction layer, as the bulk heterojunction layer is made insoluble by the thermal treatment. This is a significant advantage of the present method compared with prior art methods of manufacturing tandem cells.

In addition, between each set of steps (b), (c), (d) and (e), it is usual when constructing such tandem cells to include a further layer between the hole transporting layer and the metal oxide layer of the subsequent cell, which layer comprises a metal. This layer is said to function as a recombination layer, and has previously been believed to be essential in tandem cells. However, this layer has various disadvantages. It must be a very thin layer of metal in order to allow the passage of light therethrough. Thus, vacuum deposition of the layer is usually used, and, as explained above, that is not preferred for reasons of expense. Further, even where the metal layer is made to be very thin, the transparency of the layer is not high and the layer may reflect a proportion of the light entering the cell. This is not preferred as the cell loses efficiency if light does not reach the lower layers. The present inventors have discovered that this recombination layer is not essential to the function of the tandem cell, and indeed, when applied in tandem cells according to the present invention, is found to reduce their performance.

Preferably, the transparent first electrode is provided on a substrate. Suitable substrates include glass, plastics and cloth. It is necessary for the electrode and the substrate to be substantially transparent, to allow light to reach the layers of hole conducting polymer and electron conducting material. This gives high cell efficiency.

Preferably, the first electrode comprises a highly conductive layer that may distribute charge over the whole of its surface.

A suitable transparent electrode is indium tin oxide (ITO). However, as discussed above, the use of a transparent electrode other than ITO is preferred. Preferred transparent electrode layers may be formed from fluorine tin oxide (FTC)), a high conductivity organic polymer such as PEDOT:PSS or a metal grid—high conductivity organic polymer composite, or from materials such as gold, silver, aluminium, calcium, platinum, graphite, gold-aluminium bilayer, silver-aluminium bilayer, platinum-aluminium bilayer, graphite-aluminium bilayer, and calcium-silver bilayer, tin oxide-antimony, using methods known in the art, such as application of a solution of a salt of the required electrode material. For example, Pode et al. (Applied Physics Letters, 2004, 84, 4614-4616) describes a method of forming a transparent calcium-silver bilayer electrode; Hatton et al. (Journal of Materials Chemistry, 2003, 13, 722-726) describes a method of producing a transparent gold electrode; Neudeck and Kress (Journal of Electroanalytical Chemistry, 1997, 437, 141-156) describe the formation of laminated gold micro-meshes for use as transparent electrodes. The transparent electrode layer may be formed by application of a solution of a salt of the selected metal. For example, a platinum electrode layer is formed by application of a freshly-made solution (5×10⁻³ M) of H₂PtCl₆ in isopropanol using an air-brush.

A preferred transparent electrode layer may be formed as a silver grid under a PEDOT:PSS layer, as described by Aernouts et al. (Thin Solid Films 22 (2004) pp 451-452). Alternatively, an aluminium grid with a PEDOT:PSS overlayer or a screen printed silver grid with a screen printed PEDOT:PSS overlayer may be used (see below). Such methods of producing the transparent electrode layer may avoid the use of vacuum processing steps, in accordance with one of the aims of the invention.

Preferably, the metal oxide nanoparticle layer is formed by application of a layer of a solution of metal oxide nanoparticles to the transparent electrode layer. The solution may be applied by spin coating, doctor blading, casting, screen printing, pad printing, knife over roll printing, slot-die printing, gravure printing or ink jet printing. Preferably, the nanoparticle layer is annealed after application. Suitably, this may be carried out by heating at 210° C. for 2 min.

TiOₓ is used herein to denote a sub-stoichiometric oxide of titanium.

Preferably, the metal oxide is zinc oxide. This is advantageous as zinc oxide nanoparticles are readily soluble and may be processed into thin films at low temperatures.

Suitably, the zinc oxide nanoparticle solution may be stabilised by the addition of acids, amines, thiols or alcohols, for example, methoxyacetic acid, methoxyethoxyacetic acid, methoxyethoxyethoxyacetic acid, propylamine, octylamine, or octylthiol.

Suitable hole conducting polymers include poly(terphenylene-vinylene), polyaniline, polythiophene, poly(2-vinyl-pyridine), poly(N-vinylcarbazole), poly-acetylene, poly(p-phenylenevinylene) (PPV), poly-o-phenylene, poly-m-phenylene, poly-p-phenylene, poly-2,6-pyridine, poly(3-alkyl-thiophene) or polypyrrole substituted with thermally cleavable groups. Polythiophene derivatives substituted with thermally cleavable groups are particularly preferred. For example, polythiophenes and copolymers of thiophene with aryl monomers, such as benzothiadizole, thienopyrazine, fluorene or dialkylfluorenes, or dithienocyclopentadiene, which copolymers bear thermocleavable sidegroups are preferred.

Preferably, the thermally cleavable groups improve the solubility of the hole conducting polymer in one or more solvents. This permits the use of solution-based methods for formation of the bulk heterojunction layer.

Preferably, after thermal cleavage the hole conducting polymer contains groups capable of strong, non-covalent interactions (most preferably free carboxylic acid groups) so that the polymer forms a hard insoluble matrix. These groups are preferably formed by thermal cleavage, but may be present before thermal cleavage has taken place. For example, polymers containing free carboxylic acid groups before thermal cleavage has taken place may be used. However, such polymers (for example poly(3-carboxydithiophene) (P3CT) and poly(carboxyterthiophene-co-diphenylthienopyrazine) (P3CTTP)) are typically not soluble in organic solvents.

Preferably, the hole conducting polymer is soluble in at least one organic solvent before thermal cleavage, and is substantially insoluble in organic solvents and water after thermal cleavage. This permits a robust, insoluble bulk heterojunction layer to be formed as well as permitting the layer to be formed using solution techniques.

In a preferred embodiment, the hole conducting polymer is a polythiophene (PT) or PPV substituted with ester groups (C═O—O—R) which cleave to give free carboxylic acid groups, for example 2-methylhexylcarboxylate ester groups. Tertiary ester groups are preferred as they are easily thermally cleaved, allowing lower temperatures to be used. Preferred hole conducting polymers are poly(3-(2-methylhex-2-yl)oxycarbonyldithiophene) (P3MHOCT) and poly-[(3′-(2,5,9-trimethyldecan-2-yl)-oxy-carbonyl)-[2,2′;5′,2″]terthiophene-1,5″-diyl)-co-(2,3-diphenylthieno[3,4-b]pyrazine-5,7-diyl)] (P3TMDCTTP). The synthesis and thermal cleavage of the former polymer has been published in J. Am. Chem. Soc. 2004, vol. 126, p. 9486-9487 by Jinsong Liu et al. The synthesis and cleavage of the latter polymer is described below.

Other suitable substituents are thioesters which may cleave to give thioacids.

In an alternative embodiment, the hole conducting polymer is a polythiophene (PT) or PPV substituted with ester groups (C═O—O—R) which cleave to give free carboxylic acid groups, for example 2-methylhexylcarboxylate ester groups or trimethyl decan-2-yl ester groups, and which may then be further cleaved to remove at least some of the carboxylic acid groups. Preferred hole conducting polymers are poly(3-(2-methylhex-2-yl)oxycarbonyldithiophene) (P3MHOCT) and poly-[(3′-(2,5,9-trimethyldecan-2-yl)-oxy-carbonyl)-[2,2′;5′,2″]terthiophene-1,5″-diyl)-co-(2,3-diphenylthieno[3,4-b]pyrazine-5,7-diyl)] (P3TMDCTTP), which, when heated to around 300° C., undergo cleavage of the ester groups and subsequent loss of CO₂ to form polythiophene (PT) and poly(thiophene-co-diphenylthienopyrazine) (PTTP) respectively.

The polymers may be further substituted to alter their electronic properties with electron withdrawing or donating groups, or to alter their physical properties, such as solubility, for example with alkyl groups, or tertiary methoxyethoxyethoxy groups to convey solubility in water or ethanol. The choice of solubilising group is made according to the solvent employed during processing of the device films (i.e. organic or water miscible solvents). The solubilising chain is removed during thermocleavage and film processing and does not influence device performance at a later stage. The organisation of the molecules in the final film may show some dependence on the solubilising group.

A mixture of substituents may be used.

Preferably, the hole conducting polymer is unbranched.

The hole conducting polymer may be blended with a dye or a mixture of dyes. The hole conducting polymer may be a co-polymer, for example a block co-polymer.

In certain cases it may be preferred to use a regioregular polymer rather than a regiorandom polymer.

Preferably, the bulk heterojunction layer is provided on the metal oxide layer by coating a solution of the metal oxide nanoparticles and hole conducting polymer onto the metal oxide layer followed by removal of the solvent. Coating may be carried out by spin coating or screen printing a solution of the hole conducting polymer, or by the use of a doctor blade.

Suitable solvents include any organic or inorganic solvent: examples include chlorobenzene, chloroform, dichloromethane, toluene, benzene, pyridine, ethanol, methanol, acetone, dioxane, tetralines, xylenes, dichlorobenzene, tetrahydrofuran, alkanes (pentane, hexane, heptane, octane etc.), water (neutral, acidic or basic solution) or mixtures thereof. To the solution, small amounts of a suitable polymer (for example, polystyrene or polyethylene glycol) may be added to adjust the viscosity.

Suitable solvents also include thermocleavable solvents such as those described in WO2007/118850. These solvents have the advantage that, while not being volatile in themselves, they may be thermally cleaved to give more volatile products that may be easily removed from the bulk heterojunction layer. When forming the bulk heterojunction layer by screen printing, it is preferred to use these thermocleavable solvents.

The metal oxide in the bulk heterojunction layer is preferably ZnO.

In certain cases it may be preferred to combine one metal oxide in the metal oxide layer with a different metal oxide in the bulk heterojunction layer. This choice may be made with reference to the relative position of the electronic energy levels of the different metal oxides.

Where the metal oxide used is ZnO, and it is intended to coat an aqueous solution on to the bulk heterojunction layer in order to form a subsequent layer, the ratio of ZnO:polymer in the solution is preferably at least 1:1 but preferably around 2:1 (w/w) and in the range 1:1 to 4:1. This permits a solution used to form the second electrode to wet the surface of the bulk heterojunction layer efficiently, improving the formation of the second electrode. A lower proportion of ZnO in the layer results in poor wetting. However, if using an organic solvent based screen printing formulation then wetting is not a problem, and the above ratios are not required.

There are various considerations which determine the optimum thickness of the hole conducting polymer layer.

An exciton is generated at the spot where a photon is absorbed. This occurs throughout the bulk heterojunction layer, but mostly close to the transparent electrode. In order to generate electricity, the exciton has to reach a dissociation location (for example the electrode surface, or the bulk heterojunction/metal oxide interface) and the charge carrier has to reach an electrode (holes and electrons go to opposite electrodes).

The thicker the bulk heterojunction layer, the more likely photon absorption is to take place. A certain thickness is required in order to absorb sufficient light. A thickness giving an absorbance of around 1 (this corresponds to 90% absorbance of the light) is preferable. This was found to be achieved when a solution having a concentration of 25 mg.ml⁻¹ of P3MHOCT and from 10-50 mg.ml⁻¹ of ZnO nanoparticles in chlorobenzene was used to form the bulk heterojunction layer.

However, if the thickness is too high the average distance that an exciton or a charge carrier (a hole or an electron), has to diffuse becomes too long, because of the possibility that the exciton will recombine and produce heat, or that a free hole will meet a free electron and recombine.

The optimum thickness also depends on manufacturing considerations. Some techniques give thick films and others give thin films. It is possible to form thick layers by repetition of the film deposition step (b) and thermocleavage step (c) to build up a layer of the desired thickness. This is of particular interest where a layer is desired of greater thickness than is obtainable by, for example, a single spin coating, or where a method of layer formation is used that is prone to the formation of defects. For example, in screen printing the film quality can be lower in the sense that there are sometimes point defects, which may lead to short circuit of the device. As a practical solution to this a second print (optionally associated with removal of the screen mask) generally does not generate the point defect in the same spot. Therefore it is advantageous when screen printing films to make a layer from more than one screen printing step. The present inventors have found that the use of the thermocleavable solvents in WO2007/118850 allows screen printing to be used to construct photovoltaic devices very successfully.

As the film thickness increases, the chance of film defects (holes that allows the two electrodes to touch) leading to a short circuit decreases.

Taking all these factors into consideration, it is preferred for the bulk heterojunction layer to have a thickness of at least 10 nm. Preferred thicknesses are in the range of 30 nm to 300 nm, for example about 100 nm. If a multilayer structure is adopted, such as in a tandem cell, a larger range of thicknesses can be accommodated. For example, in a tandem cell, each active layer thickness is in the range of about 30-300 nm. In addition to this is the thickness of the metal oxide and the hole transporting layers. This means that the entire thickness of the tandem device is in the range of 100-1000 nm.

Preferably, heating of the bulk heterojunction layer is carried out at a temperature between 50 and 400° C., more preferably between 100 and 300° C., for example at a temperature of 210° C. The temperature must not be too high because at high temperatures the polymer and/or electrode material may start to degrade. Also, the temperature should be chosen with reference to the chosen starting material and the product to be obtained on thermocleavage.

Suitably, the heating may be carried out using a laser in the wavelength range 475-532 nm in order that the bulk heterojunction layer is heated without overheating of the underlying layers and the substrate.

Suitably, heating may carried out in at atmosphere without oxygen or with reduced oxygen, for example under an inert atmosphere or in a vacuum oven. This helps to prevent degradation of the polymer and/or electrode. However, the heating may be carried out without these precautions with only a slight loss in performance to the eventual device, and, with the aim of simplification of manufacture and reducing cost in mind, it is preferred not to use inert atmosphere or vacuum.

Suitably, the hole transport layer may be formed from conducting polymers such as PEDOT:PSS, PEDOT:PTS, vapour phase deposited PEDOT, polyprodot, polyaniline, or polypyrrole. PEDOT:PSS is preferred.

Preferably, the second electrode is reflective. This increases the efficiency of the device.

Preferably, the second electrode is formed of a highly conductive layer that may distribute charge over the whole of its surface. Preferably, the second electrode has a work function chosen with reference to the work function of the first electrode. Preferably, the difference between the work functions of the two electrodes is at least 0.0-3.0 eV, such as 0.0-1.0 eV. It is possible for the two electrodes to have the same work function, or to be identical.

Suitably, where the second electrode comprises a metal layer as the highly conductive layer, it is formed by coating of a dispersion of metal particles to form a thin layer.

Preferably, the second electrode comprises silver. This provides a relatively water and oxygen stable outer layer for the device, in comparison with conventionally used more reactive metals such as aluminium.

A layer of silver may be preferably formed, in view of the aims of the present invention, by application of a polymer dispersion of silver or a thermosetting screen printing silver paste in order to avoid expensive conventional vacuum deposition methods. The dispersion may be applied using spin coating, pad printing, doctor blading, casting, screen printing, roll coating or using a paint brush. This last technique has the advantage of allowing the electrode to be shaped as desired. The silver polymer layer may then be thermoset. Suitable conditions are heating at 140° C. for 3 minutes.

It is found that the device constructed in this fashion is robust. In particular, the second electrode formed as described above is scratch-resistant and much less prone to short circuits than conventional vapour deposited electrodes.

It may be advantageous in certain embodiments of the device if the transparent first electrode is the cathode. This avoids the use of low work function metals as electrodes. As such low work function metals are generally highly reactive with water and oxygen in the ambient environment, avoidance of their use improves the stability of the device. It should be noted that reversal of the polarity of the first and second electrodes does not necessarily require the reversal of the order of the metal oxide and bulk heterojunction layers. In particular, both electrodes may be formed from PEDOT-PSS, with the metal oxide and bulk heterojunction layers being arranged in either possible order in the cell.

Preferably, the method comprises the additional step of maturing the device in the dark before use. This leads to an increase in performance compared with the freshly-made device. A suitable period of time for maturation is 24-72 h. Preferably, the device is matured for at least 72 h. It is found that this time period permits the majority of the improvement in performance resulting from the maturation to be obtained.

In certain embodiments, the metal oxide layer, bulk heterojunction layer, hole transport layer and second electrode layer are preferably all formed by screen printing.

Preferably, the metal oxide layer and the bulk heterojunction layer are screen printed as solutions in a thermocleavable solvent.

In a second aspect, the present invention provides a conducting polymer based photovoltaic device formed by the method described above.

In a third aspect, the present invention provides an assembly comprising at least one photovoltaic device as described above electrically connected to another component. Where the photovoltaic device is a solar cell, the other component is preferably a power consuming device. The power consuming device may for example be a light source or a motor. The assembly may also comprise power storing means, for example a capacitor, supercapacitor or rechargeable battery. This means that light energy harvested by the solar cell can be stored until electrical power is needed. Where the photovoltaic device is an electroluminescent device, the other component is preferably a power source, for example a battery.

In a fourth aspect, the present invention provides a conducting polymer based photovoltaic device comprising the following layers:
(a) a transparent first electrode;
(b) a metal oxide layer, wherein the metal oxide is selected from the group consisting of: ZnO, TiO₂ and TiOₓ;
(c) a bulk heterojunction layer comprising metal oxide nanoparticles and a hole conducting polymer which has been thermally treated to decrease its solubility, wherein the metal oxide is selected from the group consisting of: ZnO, TiO₂, TiOₓ, CeO₂ and Nb₂O₅;
(d) a hole transporting layer; and
(e) a second electrode.

Preferably, the device comprises no layers or coatings that exclude oxygen and water from contact with the bulk heterojunction layer while the device is in use. However, the device may suitably comprise a protective layer that protects the surface from scratching and similar damage, while not preventing the access of water and oxygen to the device.

Suitably, the device further comprises a UV filter. However, this feature is not necessarily preferred. The present inventors have found that, in certain cases at least, the presence of a UV filter leads to faster degradation of the performance of the cell, although also to higher values of I_{SC}.

Suitably, the device may comprise more than one of the set of layers (b), (c) and (d) between the electrodes (a) and (e). Such a cell is known as a tandem cell.

The present invention further provides:

a compound having the formula:

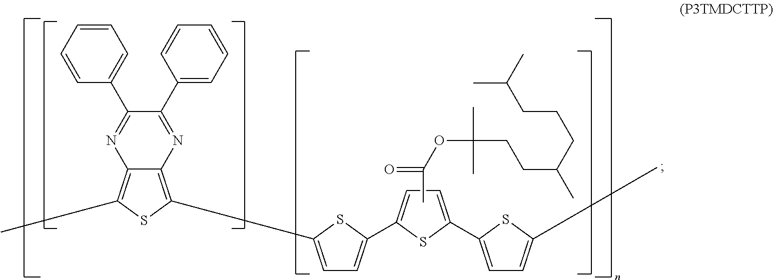

a compound having the formula:

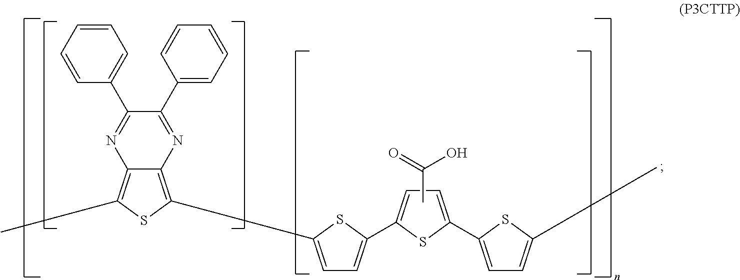

the use of P3TMDCTTP, P3CTTP or poly(thiophene-co-diphenylthienopyrazine) (PTTP) in the bulk heterojunction layer of a photovoltaic device; and
a method of forming P3CTTP by thermal cleavage of P3TMDCTTP at 210° C.

The invention further provides a method of forming poly(thiophene-co-diphenylthienopyrazine) (PTTP) by thermal cleavage of P3TMDCTTP or P3CTTP at 310° C.

A general description of the function of the layers of the cells of the invention is provided below:

Electrode layers: One of the electrodes is necessarily transparent and both electrodes may be transparent. Typically, the first electrode is the front electrode and therefore it is transparent. The back electrode does not need to be transparent. The purpose of the front electrode is to admit light to the device film. The first electrode may be a pure transparent conductor (ITO, TCO, PEDOT) or it may be a composite of a conducting metal grid allowing from some light to come through with a conducting polymer on top (such as PEDOT:PSS, PEDOT:PTS, polyprodot, polyaniline, polypyrrole or other similar conducting polymers known in the art).

The metal oxide layer functions as an electron transporting layer. The metal oxide layer is placed on top of the first electrode. The ZnO is optically transparent (no colour) and only transports electrons.

Active layer: this comprises the hole conducting polymer and dispersed metal oxide nanoparticles in a bulk heterojunction. In this layer light is absorbed to form an exciton, and the exciton dissociated to a hole and an electron that can percolate through the interpenetrating network of polymer and oxide. The holes are transported in the polymer and the electrons are transported in the oxide.

On top of the active layer PEDOT:PSS or a similar conducting polymer is employed as a hole transporting layer.

Second/back electrode: Any highly conducting material such as a metal. The purpose is to remove the charges as efficiently as possible.

Explanation of the working of the device: The charges generated in the active layer can diffuse round in the two interpenetrating networks (holes in the polymer network and electrons in the oxide network). However electrons can only leave through the oxide layer and holes can only leave through the hole transporting layer. Thus, an electrical potential difference is created between the two electrodes.

The cells may be realised in reverse order.

Tandem cells: When stacking cells the holes coming through the hole transporting layer from the first cell meet the electrons in the metal oxide layer coming from the next cell and recombine. The result is that the voltage of the first and the second cell are added. However if the first and the second cell do not produce roughly the same amount of charge some charges are lost in the recombination layer between the first and second cell, i.e. some of the holes or electrons will not find a partner to recombine with.

Features described in connection with any aspect of the invention can also be applied to any other aspect of the invention.

### BRIEF DESCRIPTION OF THE FIGURES

FIG. 1 shows the construction of a cell of the invention.

FIG. 2 shows the construction of a tandem cell of the invention.

FIG. 3 shows the device testing results for a device of FIG. 1.

FIG. 4 shows the dark storage testing results for a device of FIG. 1.

FIG. 5 shows device degradation over time for a device of FIG. 1.

FIG. 6 shows the improvement in performance over the first 42 h of the life of a device of FIG. 1.

FIG. 7 shows the subsequent degradation in performance of the device as in FIG. 6.

FIG. 8 shows a comparison between two cells to be used in Example 8 before testing.

FIG. 9 shows the effect of temperature and a UV filter on the stability of the devices of FIG. 8.

FIG. 10 shows the results of testing a tandem cell of the present invention.

### EXAMPLES

General Methods

Regiorandom poly(3-(2-methylhex-2-yl)-oxy-carbonyldithiophene) (P3MHOCT) was synthesised by the method of Jinsong Liu et al. (J. Am. Chem. Soc. 2004, vol. 126, p. 9486-9487). The synthesis is outlined below:

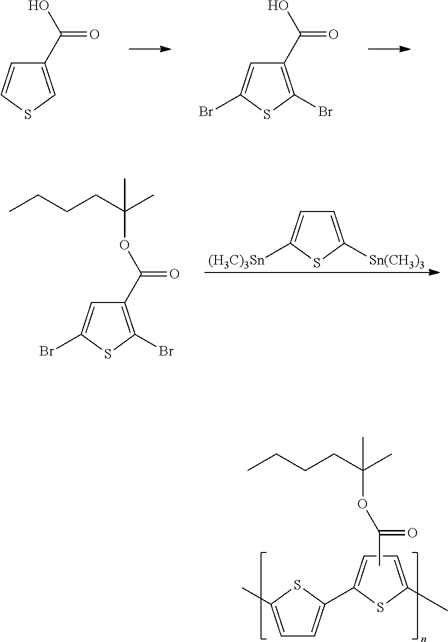

The P3MHOCT as synthesised had the following properties: Mₙ=11600 g.mol⁻¹; M_{w}=28300 g.mol⁻¹; 27500 g.mol⁻¹; PD=2.6. The P3MHOCT was used as a solution in chlorobenzene, prepared by gentle shaking at room temperature. The use of elevated temperature was avoided in this step. The solution was stable for extended periods in a glove box or tightly sealed container.

P3TMDCTTP was synthesised as set out below:

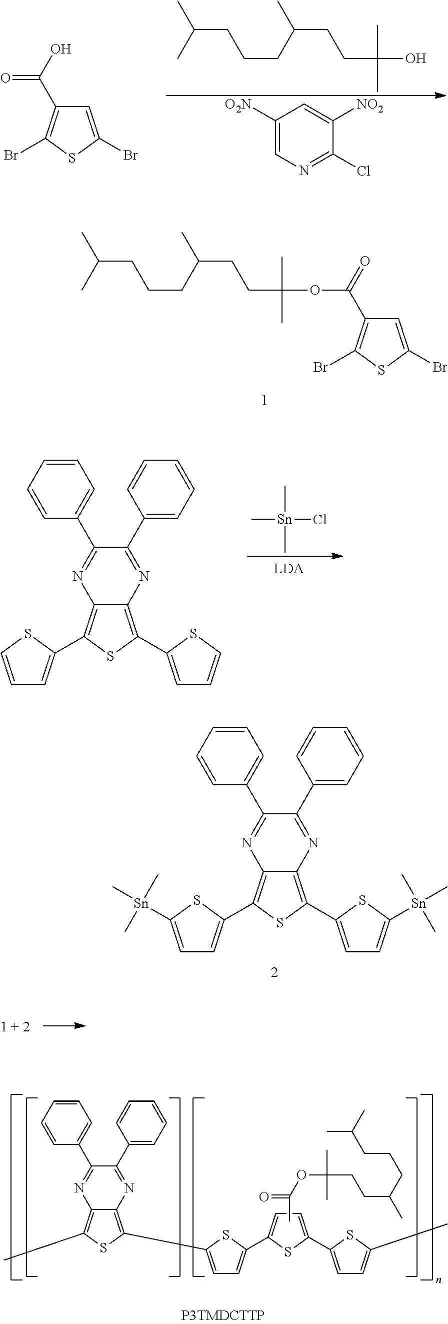

Synthetic procedure to the thermocleavable low band gap polymer P3TMDCTTP.

### Synthesis of (2,5,9-trimethyldecan-2-yl)-2,5-dibromothiophene-3-carboxylate

2,5-Dibromothiophene-3-carboxylic acid (10.0 g, 35 mmol) and 2-chloro-3,5-dinitropyridine (7.8 g, 38.5 mmol 1.1 eq.) was dissolved in dry pyridine under argon. The mixture was heated to approx. 40° C. for 30 minutes. 2,5,9-Trimethyl-decan-2-ol (7.7 g 38.5 mmol 1.1 eq) was added and the mixture is stirred at 120° C. overnight. After cooling to ambient temperature, the mixture was poured into a mixture of water (300 mL), light petroleum (300 mL) and NaHCO₃(aq) (100 mL, 2M). The aqueous phase was extracted with light petroleum (3×100 ml), and the combined organic phases were dried over MgSO₄ and evaporated to give a light yellow oil. The product was purified by flash chromatography using heptane as base solvent and extracting the desired product with 2% ethyl acetate to give a colourless oil. Yield: 5.1g (34%). ¹H NMR (CDCl₃): δ: 0.88 (t, 9H, J=7Hz), 1.09-1.32 (m, 8H), 1.35-1.44 (m, 2H), 1.56 (s, 6H), 1.80-1.92 (m, 2H), 7.29 (s, 1H). ¹³C NMR (CDCl₃) δ: 19.7, 22.6, 22.7, 24.8, 26.1, 26.2, 28.0, 30.8, 33.0, 37.1, 38.2, 39.3, 85.0, 110.9, 118.0, 131.9, 133.4, 159.9.

### Synthesis of 2,3-diphenyl-5,7-bis(5-(trimethylstannyl)thiophen-2-yl)thieno[3,4-b]pyrazine

A solution of LDA was prepared as follows: THF (10 mL) was cooled to −10° C. and n-BuLi (1.6 M, in hexane, 10 mL, 16 mmol) was added dropwise. The mixture was stirred for 10 min. and di-isopropylamine (2.5 mL, 18 mmol) in THF (7.5 mL) was added drop wise. The mixture was stirred for 30 min. at −10° C. and used directly. LDA solution (20 mL, 11 mmol, 5 eq.) was added drop wise to a solution of 2,3-diphenyl-di-thiophen-2-yl-thieno(3,4-b)pyrazine (1.0g, 2.2 mmol) in THF (50 mL) at −78° C. A colour change from green to dark purple was observed. After 1 hour at −78° C. (2.6 g, 13 mmol) of trimethylstannyl chloride dissolved in dry THF (7 mL) was added over a period of 5 min. After the mixture had reached ambient temperature it was evaporated to dryness and recrystallized from heptane, to give a purple solid. Yield: 1.1g (64%). ¹H NMR (CDCl₃): δ: 0.44 (s, 18H), 7.22 (d, 2H, J=4Hz), 7.33-7.40 (m, 6H), 7.62 (dd, 4H, J1=8 Hz, J2=1 Hz), 7.87 (d, 2H, J=4Hz). ¹³C NMR (CDCl₃) δ: −8.2, 124.9, 126.1, 128.0, 128.9, 130.0, 135.6, 137.5, 139.2, 139.7, 140.2, 152.7

### Synthesis of Regiorandom poly-[(3′-(2,5,9-trimethyldecan-2-yl)-oxy-carbonyl)-[2,2′;5′,2″]terthiophene-1,5″-diyl)-co-(2,3-diphenylthieno[3,4-b]pyrazine-5,7-diyl)] (P3TMDCTTP)

2,3-diphenyl-5,7-bis(5-(trimethylstannyl)thiophen-2-yl)thieno[3,4-b]pyrazine (300 mg, 0.3854 mmol) and (2,5,9-trimethyldecan-2-yl)-2,5-dibromothiophene-3-carboxylate (180.5 mg, 0.3854 mmol) were dissolved in dry toluene under argon, Pd₂dba₃ (12.5 mg,) and Tri-t-butylphosphonium tetrafluoroborate (25 mg) were added. N-methyldicyclohexyl amine (0.5 ml) was added after 5 min. The mixture was refluxed for 4 days. The mixture was concentrated to half the original volume on a rotary evaporator in vacuum and the residue was poured into 5 volumes of methanol. The precipitate was isolated by filtration, washed with methanol and dried to give a dark green powder. Yield: 198 mg (67%). ¹H NMR (CDCl₃): δ: 0-79-0.86 (m, 9H), 1.05-1.35 (m, 10H), 1.50-1.60 (m, 6H), 1.74-1.90 (m, 2H), 7.30-7.50 (m, 9H), 1.51-1.73 (m, 6H) . SEC: Mₙ=1800, M_{w}=2900, Mₚ=2500, PD=1.6.

Aqueous PEDOT-PSS was purchased from Aldrich as a 1.3 wt % aqueous solution and used as received.

PEDOT:PSS for screen printing was purchased from Agfa (Orgacon 3000 and 5000 series, specifically tested Orgacon 3040, and 5010).

Glass substrates with a 100 nm layer of ITO and a sheet resistivity of 8-12 Ω.square⁻¹ were purchased from Delta technologies and cleaned by consecutive ultrasonication in acetone, water and isopropanol for 5 min followed by drying immediately prior to use.

Alternatively, an aluminium/PEDOT:PSS composite electrode may be prepared as follows:

A 100 nm thick layer of aluminium was applied to the substrates by thermal evaporation at a pressure <1.10⁻⁶ mBar. Standard ORDYL 940 photonegative photoresist (4615 from www.megauk.com) was applied by cold lamination onto the substrate with an evaporated aluminium electrode. The photoresist was illuminated for 45 μm through a photonegative mask of the anode grid pattern consisting of parallel lines with a thickness of 250 μm and a spacing of 500 The geometric fill factor of the anode was thus 50%. The resist was developed (developer for 4615 from www.megauk.com) and etched carefully in 10% HCl(aq) containing FeCl₃ (5% wt/V) until the aluminium at the exposed area had dissolved. Then the resist was removed by subjecting the substrates to ultrasound in ethanol whereby the photoresist detaches efficiently within 5 minutes The substrates with the aluminium pattern were washed with ethanol and dried at 25° C. for 10 minutes before optional application of a thin semi-transparent silver layer (5 nm) by evaporation followed by the PEDOT:PSS layer by spin coating at 2800 rpm.

For the back electrode a silver migration resistant polymer based on Dupont 5007 and capable of being cured at 130-140° C. for 3 minutes was used.

Zinc oxide nanoparticles were prepared by a procedure similar to that reported in Beek et al., J. Phys. Chem. B 109 (2005) p 9505. In a 3-litre conical flask, Zn(OAc)₂.2H₂O (29.7 g) was dissolved in methanol (1250 ml) and heated to 60° C. with stirring. KOH (15.1 g) dissolved in methanol (650 ml) and heated to 60° C. was added over 30 s. The mixture becomes cloudy towards the end of the addition. The mixture was heated to gentle reflux and after 2-5 min the mixture became clear and was stirred at this temperature for 3 h during which time precipitation starts. The magnetic stirrer bar was removed and the mixture left to stand at room temperature for 4 h. The mixture was carefully decanted leaving only the precipitate. The precipitate was then resuspended in methanol (1000 ml) and allowed to settle for 16 h. The mixture was then decanted carefully making sure that as much of the supernatant was removed as possible without the precipitate becoming dry. Chlorobenzene (35 ml) was added immediately and the precipitated nanoparticles dissolved giving a total volume of 45 ml. The typical concentration of a solution prepared in this manner was 200 mg.ml⁻¹, depending on the loss of nanoparticles during decanting of the supernatant. As an alternative to decantation, centrifuging of the mixture in methanol may be used, and this allowed the isolation of higher and more consistent yields of nanoparticles; however, the nanoparticles dissolved less easily and in a lower concentration in chlorobenzene when prepared by this method. The final solution of ZnO nanoparticles in chlorobenzene typically contains 10-20% methanol as free solvent and as solvent bound to the zinc oxide nanoparticles. The concentration of the ZnO nanoparticles in solution was determined by evaporation of the solvent from 1 ml of the solution at 80° C. for 1 h followed by careful weighing. The solution was stable for extended periods in a glove box or a tightly sealed container.

Solutions of P3MHOCT or P3TMDCTTP and zinc nanoparticles in chlorobenzene were prepared by gentle shaking at room temperature, and were used within 24 h. Poorer results were obtained when older solutions were used. This is thought to be due to the basic nature of ZnO causing some hydrolysis of the ester groups of the polymer.

Resistivity of electrodes was determined using a four-point contact probe from Jandel (www.jandel.com) in conjunction with a Keithley 2400 Sourcemeter. The value sheet resistivity was obtained by passing a series of currents (low to high current) through the film. In order to avoid offsets in the sourcemeter and effects of thermovoltages the same level of current was passed in both directions. The sheet resistivity was determined from an intermediate current range where the resistivity is independent of the current.

### Example 1

### Preparation of the Single Cell Device

For the very best results, the active layer was prepared in a glove box by means of spincoating. However, the active layer may equally be prepared under ambient conditions and using simple casting for the film formation with a small loss in performance.

To freshly cleaned glass-ITO substrates from which a part of the ITO had been removed by etching was applied a layer of ZnO nanoparticles by spincoating at 800 rpm of a chlorobenzene solution of ZnO nanoparticles as prepared above. The concentration of the solution used should be such as to permit the formation of a layer having no significant pinhole formation, but sufficiently low that the film thickness does not cause the conduction of the layer to be too low. For example, a concentration of 50 mg.ml⁻¹ may be used. The dried nanoparticle film was annealed for 2 min on a hotplate at 210° C., and the substrate cooled.

An active layer consisting of both ZnO nanoparticles and P3MHOCT was spincoated on to the ZnO layer at 800 rpm using a chlorobenzene solution containing a 50 mg.ml⁻¹ concentration of ZnO and a 25 mg.ml⁻¹ concentration of P3MHOCT, as the optimum ratio for ZnO:P3MHOCT was found to be 2:1 (w/w). The dried film was heated on the hotplate at 210° C. for 2 min in order to convert P3MHOCT to P3CT (poly-(3-carboxydithiophene)) as shown below, which conversion may be observed by a colour change from burgundy to bright red, and by the loss of solubility of the layer in chlorobenzene.

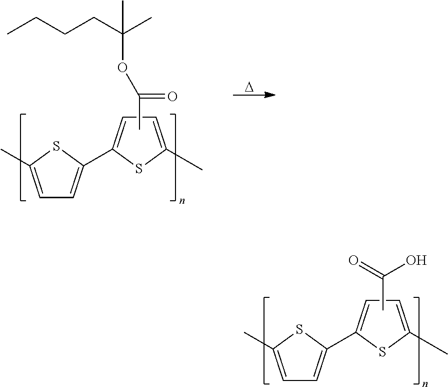

A layer of PEDOT-PSS was then applied to the active layer by spincoating or casting of the commercially available 1.3 wt % solution under ambient conditions. Spincoating was carried out by applying a coating the solution in a single smooth action followed by spinning at 2800-3500 rpm.

The conducting silver electrode was then applied to the PEDOT-PSS layer under ambient conditions. This was successfully achieved using any of: spincoating, doctor blading, casting, screen printing, and application using a paintbrush; all of which methods resulted in a thin electrode having a sheet resistivity of 0.05-22 Ω.square⁻¹. The silver electrode was cured at 130-140° C. for 3 min. The device was then cooled and was ready to use. However, for best results the device should be stored in the dark for a period of time before use. The inventors have found that, while improvements continue on dark storage of the device over long periods, the majority of the improvement is observed after the device is stored for 72 h in the dark.

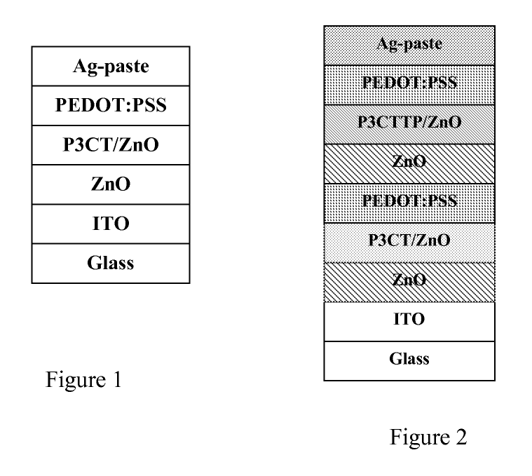

The device as prepared comprised two cells each having an active area of 1 cm². The cross sectional structure of the device is shown in FIG. 1. The device was not encapsulated, and could be handled in air without problems.

### Example 2

### Alternative Single Cell Device

A device was prepared as described above, except that the layer of P3MHOCT, once coated, was heated on the hotplate at 300° C. in order to decarboxylate the material and convert it at least partially to polythiophene (PT).

### Example 3

### Preparation of Tandem Cell Device

The formation of the zinc oxide films, the polymer-zinc oxide nanoparticle films and the thermocleavage were carried out in a glovebox. The PEDOT:PSS films were applied in ambient air. Thus, for the tandem cells this required removing the substrates from the glovebox environment after the first junction had been prepared followed by reintroduction into the glovebox after the PEDOT:PSS electrode had been applied and dried. The second junction was then prepared in the glovebox. Freshly cleaned glass-ITO substrates where part of the ITO had been removed by etching were used and firstly a layer of zinc oxide nanoparticles were spincoated at 800 rpm from a chlorobenzene solution (50 mg.mL⁻¹). The dried nanoparticle film was annealed for 2 min on the hotplate at 210° C. The substrate was then cooled and the active layer was spincoated at 800 rpm from chlorobenzene with P3MHOCT (25 mg mL⁻¹) or P3TMDCTTP (25 mg.mL⁻¹) and the zinc oxide nanoparticles (50 mg mL⁻¹). After the film had dried it was heated on the hot plate at 210° C. for 2 min whereby P3MHOCT is converted to P3CT and P3TMDCTTP is converted to P3CTTP. The conversion is in the case of P3MHOCT associated with a clearly visible color change from burgundy red to a bright red color. In the case of P3TMDCTTP the conversion is not as clearly visible to the eye but a distinct change in color from a clear green to a more pale tone is visible.

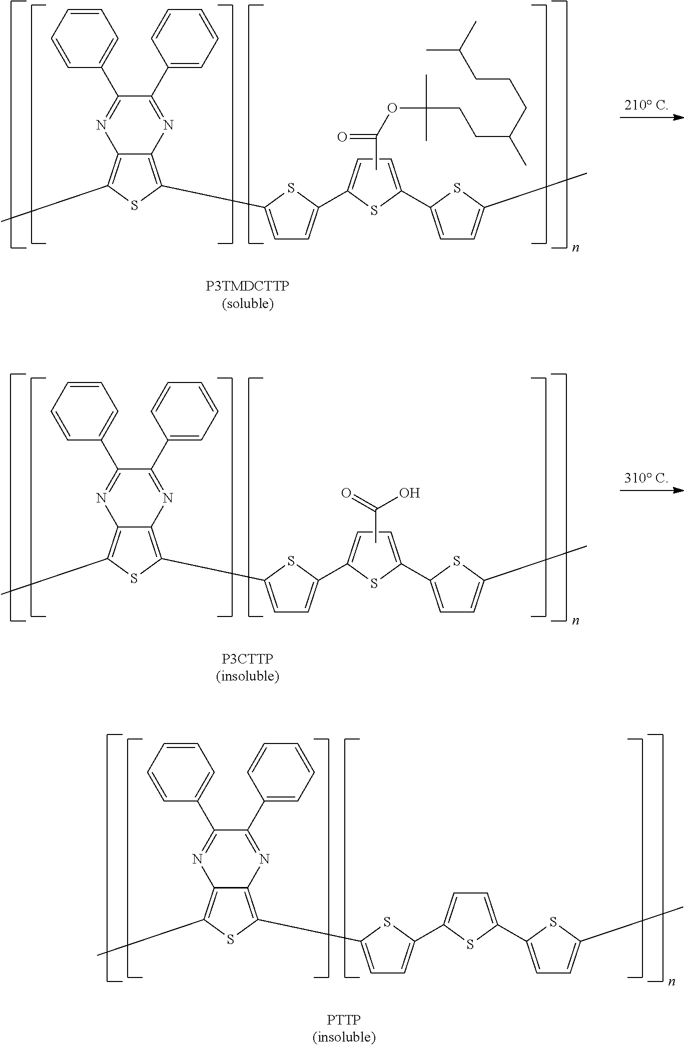

The completeness of the thermocleavage was tested by rubbing a cotton bud wetted in chlorobenzene across an area of the film that was not going to be part of the active area. The cleaved films were completely insoluble. The substrates with the composite films were removed from the glovebox and a layer of PEDOT:PSS was applied by firstly layering the PEDOT:PSS solution over the substrate and then spinning the substrate at 2800 rpm. The films were then dried at 120° C. for 10 minutes in air and then reintroduced into the glovebox in order to add a further set of active layers in order make a tandem device. Once the required number of sets of active layers had been applied, a silver back electrode was applied as a silver migration resistant polymer thick film conductor (based on Dupont 5007) that can be cured at 130-140° C. for 3 minutes. The silver electrode was applied by doctor blading through a mask giving two devices on each substrate with a quadratic active area measuring 1 cm². The devices were tested when freshly made but as observed above they improved upon standing in the dark for 24 hours and characterization was generally carried out after 24 hours in the dark. A possible cross sectional structure of the device is shown in FIG. 2.

### Example 4

### Preparation of Photovoltaic Device by Screen Printing

A small module comprising 5 cells in series was realised on a flexible plastic (polyethyleneterephthalate, PET) substrate with an overlayer of ITO that had been etched to match the 5 active areas of the device.

ZnO nanoparticles were prepared as a 50 mg mL⁻¹ solution in the thermocleavable solvent 2,5-dimethylhexyloxy-phenyloxy-carbonate (WS-1) (WO2007/118850). The solution was prepared by adding to WS-1 a stock solution of ZnO nanoparticles (200 mg mL⁻¹) that had been stabilised with methoxyethoxy acetic acid (MEA) (40 mg mL⁻¹) in a 80:20 (v/v) solution of chlorobenzene and methanol. After mixing the chlorobenzene and methanol was evaporated giving the final solution of ZnO in WS-1.

This solution was screen printed onto the PET-ITO pattern such that the printed ZnO layer covered the ITO pattern. The screen printing was performed with a 140 mesh screen and the squeegee speed was 550 mm s⁻¹. The printing speed was not critical but faster speeds were preferred. The screen was tested in the range of mesh from 90-220 and was not critical but 140-180 mesh was preferred. The printed film was dried at 70° C. for 1 hour, 150° C. for 2 hours and left in the ambient air for 20 hours to become insoluble. The active layer was then printed as a solution in WS-1 that was 25 mg mL⁻¹ P3MHOCT, 50 mg mL⁻¹ ZnO and 10 mg mL⁻¹ MEA. The solution was prepared by dissolving P3MHOCT in chlorobenzene followed by microfiltering and mixing with MEA stabilised ZnO nanoparticles in WS-1. Evaporation of the chlorobenzene and methanol gave the final screen printing formulation that was screen printed as above through a 140 mesh screen with a squeegee speed of 55 mm s⁻¹. The printed pattern exposed the ITO in one end of each cell to allow for the serial connection later. The film was dried at 150° C. for 2 hours. A second print was employed to reduce the effect of pinholes and short circuits.

PEDOT:PSS (Orgacon 5010 from Agfa) was screen printed in a pattern matching the active layer on top and dried at 120° C. for 15 min.

Silver paste (Dupont 5007) was screen printed through a 120 mesh screen at a speed of 550 mm s⁻¹ in a pattern that defined the active area of the devices and connected to the ITO of the adjacent cell making a serial connection. The Ag paste was cured at 140° C. for 3 min. The device was ready to use and gave a voltage of typically 2.1-2.5 V and a short circuit density of 0.03-1.2 mA cm⁻². Devices with two prints of the active layer gave lower current densities but generally had a better voltage due to fewer short circuits.

Device Testing

The devices were illuminated in the ambient air using a solar simulator from Steuernagel Lichttechnik, KHS 575. The luminous intensity and emission spectrum of the solar simulator approaches AM 1.5G and was set to 1000 W.m⁻² using a precision spectral pyranometer from Eppley Laboratories (www.eppleylab.com). The incident light intensity was monitored continuously every 60 s during the measurements using a CM4 high temperature pyranometer from Kipp and Zonen (www.kippzonen.com). Both instruments are bolometric. The variation in incident light intensity during the testing (150 h) was less than 5% and no corrections were made. No corrections for mismatch were made. IV-curves were recorded with a Keithley 24-sourcemeter from −1V to +1V in steps of 10 mV with a speed of 0.1 s.step⁻¹.

Lifetime Testing Under Accelerated Conditions

“Accelerated conditions” denotes the following test conditions: 1000 W.111⁻², 72±2° C., ambient atmosphere, and 35±5% humidity.

The devices were kept under short circuit conditions and the short circuit current (I_{SC}) measured every 1 min. Every hour an IV curve was recorded from −1V to +1V.

Dark Storage Experiments

A series of cells was prepared and their initial performance tested. The first set of cells was then subjected to the lifetime measurements as described above while the remaining cells were kept in the ambient atmosphere in the dark at 25° C. and a relative humidity of 35±5%. Every 150 hours a fresh cell that had been stored in the dark was subjected to an accelerated test. Experiments of this sort have taken place over a period of six months and indicate that storage of the devices in the dark over that period was possible without noticeable degradation.

The dependence of the performance as a function of incident light intensity was carried out at a constant temperature of 72±2° C. in a non-transparent black box with an opening the at could be covered with an appropriate netral density (ND) filter) (Thorlabs Inc.). The incident light intensity was set to 1000 W.111⁻² without ND filter. ND filters with a transmission of 80%, 63%, 50%, 40%, 32%, 10%, 5% and 1% were each placed in front of the device and the short circuit current was recorded.

The efficiency was determined for the devices at 1 sun (1000 W.m⁻²) and gave V_{oc}=0.516, I_{sc}=1.00 mA.cm⁻², fill factor (FF)=0.35% and PCE=0.18%. At 0.1 sun (100 W.m⁻²) the values obtained were V_{oc}=0.530, I_{sc}=0.289 mA.cm⁻², fill factor (FF)=0.30% and PCE=0.46%. The performance is thus significantly better towards lower light intensities.

### Example 5

### Lifetime Testing of Device of Example 1

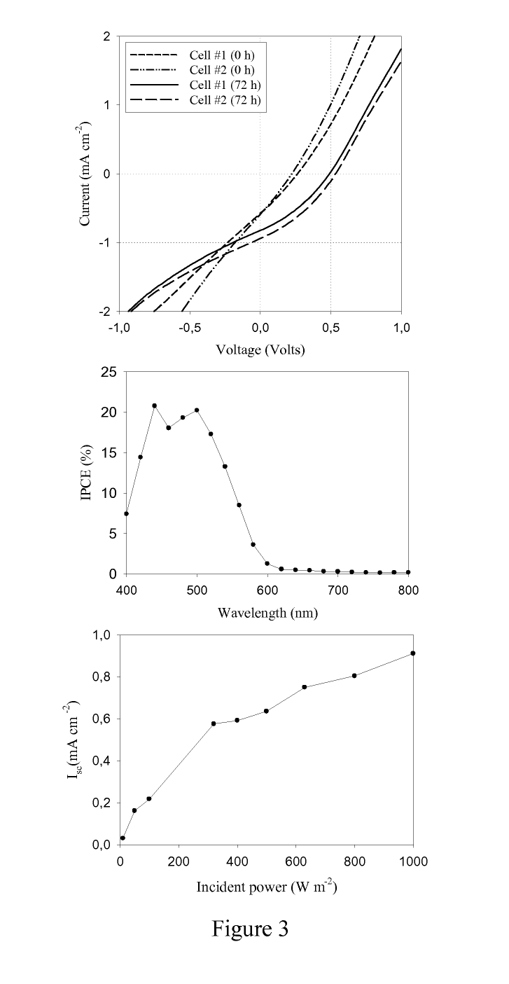

The results of the lifetime testing of the devices of Example 1 are shown in FIG. 3.

The devices were found to perform relatively poorly when freshly prepared, and improved after storage in the dark overnight as observed earlier for devices based on zinc oxide nanorods and P3HT (see Olson et al., J. Phys. Chem. C 111 (2007) 16670). Storage in the dark under ambient conditions for extended periods of time did not improve the performance.

In terms of stability during operation the devices however performed quite well. Surprisingly, they worked well for 100 hours or more under accelerated conditions.

The use of metal oxides in polymer solar cells has previously been shown to be problematic due to an equilibrium between oxygen from the atmosphere and oxygen in the oxide (see M. Lira-Cantu et al., Solar Energy Materials and Solar Cells 90 (2006) 2076; M. Lira-Cantu et al., Chemistry of Materials 18 (2006) 5684-5690; M. Lira-Cantu et al., J. Electrochem. Soc. 154 (2007) B508). This interplay with oxygen was shown to be detrimental to hybrid cells based on metal oxides (TiO₂, CeO₂, TiO₂—CeO₂, Nb₂O₅, and ZnO) and a polyphenylenevinylene (PPV) material such as MEHPPV. The equilibrium between oxygen atoms at the surface of the metal oxide and molecular oxygen in the atmosphere is thought to influence the electronic structure of the oxide and rule the ability of the charge carrier injection from the light harvesting polymer to the oxide. For most of these devices oxygen is required for function while the devices also degrade in oxygen. In vacuum or inert atmospheres the materials in the devices do not degrade but unfortunately the devices do not work well as solar cells as the short circuit current decreases rapidly when oxygen is removed. It was thus surprising that this system performs so well in terms of stability.

This probably also explains why the devices prepared in the glovebox do not perform optimally when removed from the glovebox but work better after being left to equilibrate for a period of 24-72 hours as shown in FIG. 3.

The case presented here represents a significant improvement over the devices based on MEHPPV and ZnO in terms of both performance and stability. One possible explanation for this could be that the carboxylic acid groups of P3CT efficiently bind covalently to the surface of the zinc oxide nanoparticles. This has been proposed earlier in the case of TiO2-P3CT-P3HT hybrid solar cells while no details on the stability were given (see J. S. Liu et al., J. Am. Chem. Soc. 126 (2004) 9486).

### Example 6

### Dark Storage Testing of Device of Example 1

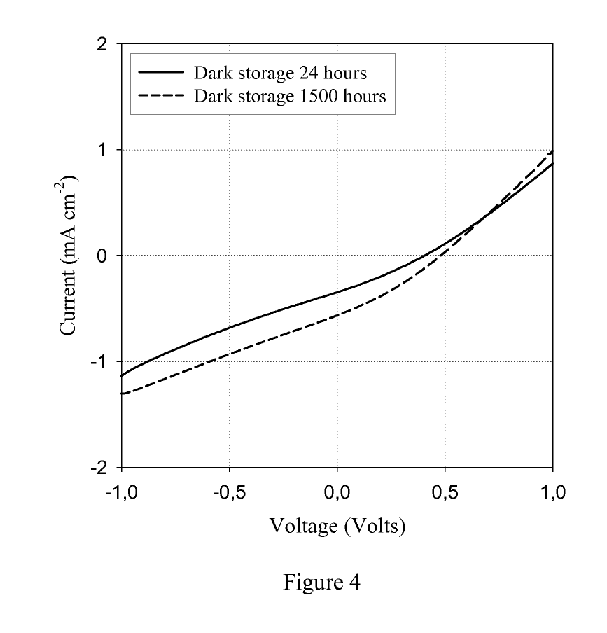

The results of the dark storage testing of Example 1 are given in FIGS. 4, 5, 6 and 7.

Traditionally, polymer solar cells are subject to degradation in the dark and this poses a severe problem. Storability in the dark for several months is an absolute necessity and while it has been shown for encapsulated devices (see G. Dennler et al., J. Mater. Res. 20 (2005) 3224-3233 and C. Lungenschmied et al., Sol. En. Mater. Sol. Cells 91 (2007) 379-384). It is highly desirable to find a technology that is stable in the dark under ambient conditions without special requirements for encapsulation etc. It was apparent from the results herein that the devices of Example 1 have the potential for very long ambient dark storage without significant degradation in performance.

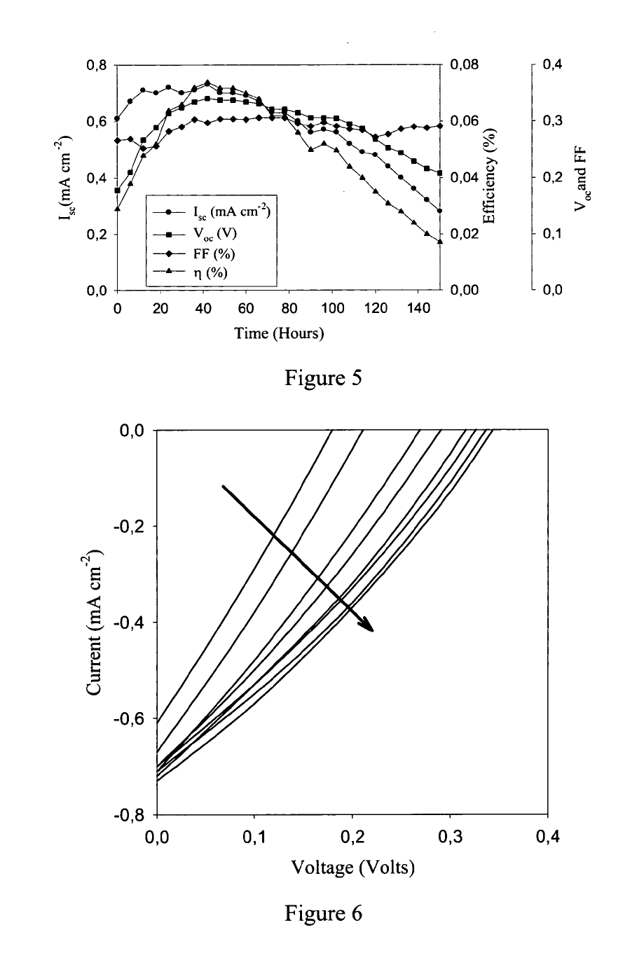

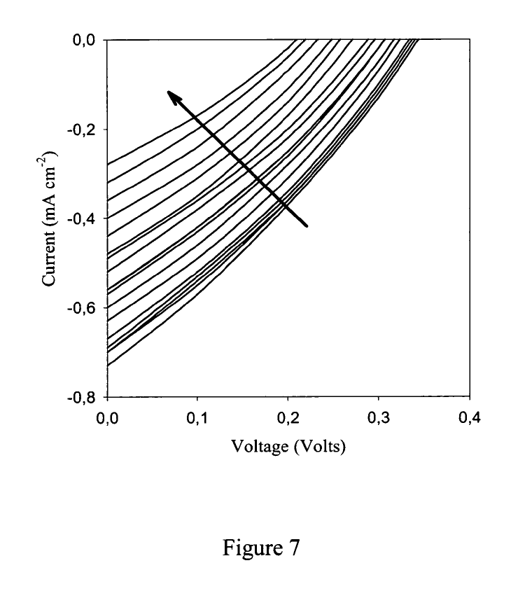

Data are shown in FIG. 4 for a dark storage test. Once the devices are taken into operation their performance is quite constant under accelerated conditions (1000 W.m⁻², 72±2° C., ambient atmosphere, 35±5% relative humidity). Operation for more than 100 hours with degradation to 80% of the initial performance is possible in terms of current as shown in FIG. 5. The device performance typically improves during the first 40-50 hours as shown in FIG. 6 followed by degradation of the performance as shown in FIG. 7. Interstingly, the fill factor (FF) remains quite constant while both I_{sc} and V_{oc} are subject to increase in the beginning and decrease during the degradation phase.

### Example 7

### Testing of the Device of Example 2

The device of Example 2 was subject to preliminary testing for comparison with the device of Example 1. Preliminary results suggest that similar performance can be obtained for both P3CT:ZnO and PT:ZnO cells which may indicate that bonds or interactions between the carboxylic acid moieties on P3CT and ZnO are not important for the electronic contact as has been suggested (see J. S. Liu et al., J. Am. Chem. Soc. 126 (2004) 9486). However, the conversion of P3CT to PT at 300° C. in the presence of ZnO may altermatively imply that only the free carboxylic acid groups decarboxylate and the carboxylic acid groups that are interacting with ZnO remain. This would explain the similarity in the results for the devices of Example 1 and Example 2.

### Example 8

### Lifetime Testing with UV Filter

Where a UV cut-off filter was used in testing the device, a FGL400S filter from Thorlabs Inc was placed in front of the cell. IPCE measurements were carried out using the set-up described in Krebs and Jorgensen, Rev. Sci. Instr. 74 (2003) pp 3438, modified to use a longer source to grating distance and cylindrical lenses to improve the incident light intensity and spectral bandwidth. The spectral bandwidth was 10 nm and the incident light intensity was in the range of 480-130 μW.cm⁻² in the range of wavelengths from 800 to 400 nm.

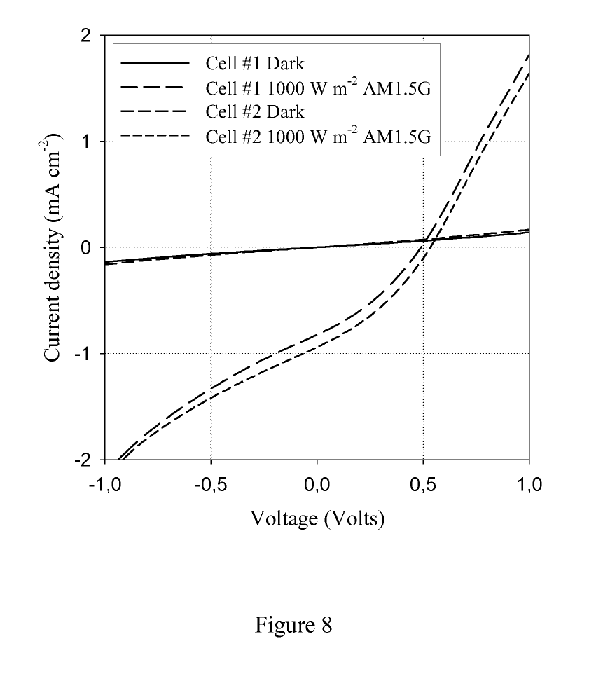

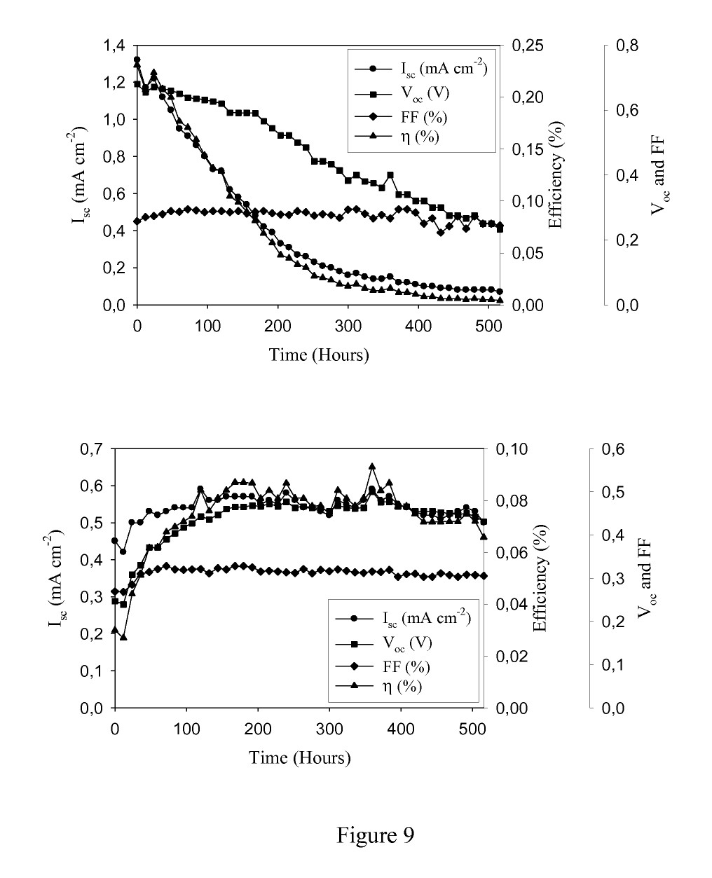

The degradation rate when testing a device employing a UV-filter with a cutoff at wavelengths below 400 nm at a temperature of 25° C. using air cooling gave two interesting findings. The results are shown in FIGS. 8 and 9.

Two cells having similar performance and on the same substrate were tested before the start of the experiment, and the results are shown in FIG. 8. Cell #1 was covered by a UV filter with a cut-off at wavelengths below 400 nm and Cell#2 was illuminated without the filter. This gave the lifetime profiles shown in FIG. 9.

The degradation rate was significantly slower at 30° C. as shown in FIG. 9.

Interestingly, the performance of Cell#1 increased dramatically by the simple application of the UV filter. This observation can be explained in part by an optical effect of the filter as the response in terms of V_{oc} and I_{sc} depended somewhat on the position of the edge of the filter with respect to the cell. The placement of the UV filter was made so that it affected the values of V_{oc} and I_{sc} the least.

This observation of improved current and voltage probably also has its roots in the avoidance of direct band gap excitation of zinc oxide. It has been shown that UV-illumination of zinc oxide nanoparticles does influence the electrical properties in a positive manner as conductivity increases (see Verbakel et al., Appl. Phys. Lett. 89 (2006) 102103 and Beek et al, Adv. Funct. Mater. 16 (2006) 1112).

However, the use of the UV filter also increased the rate of degradation of the performance of the cell, as can be seen by comparing the results in FIG. 9.

In terms of projecting the operational lifetime for a device based on this technology under indoor conditions the results indicate that very long lifetimes are possible. Assuming that the operation temperature is below 30° C. and the incident light is 50-100 W.m⁻², it is anticipated that these devices can operate for a year or more. It should be emphasized that this is for the naked device with no encapsulation.

### Example 9

### Comparison of Devices of Example 1 with Batteries

The technology presented here already performs well enough for simple niche applications and compare well to small batteries in terms of the amount of charge the device can produce during its service life. One of the niche applications of polymer solar cells is anticipated to be as power supplies for small electronic devices.

A direct competitor to the polymer solar cell is the battery that has obvious advantages in terms of energy storage and operation in the dark. The polymer solar cells offer flexibility, a thin outline, light weight and possible environmental benefits in terms of biodegradability.

The comparison between batteries and polymer solar cells is naturally difficult as there is a certain degree of incongruence between the two technologies. The purpose of the comparison is thus to underline the contrasts and find the areas where the polymer solar cells may offer distinct advantages over batteries.

The polymer solar cells will naturally only be applicable when light is available as the source of energy and their energy output depends on the incoming light flux. It is assumed that the designer is aware of these factors and that the application is made such that the polymer solar cell performance is in compliance with the electrical supply requirements of the electronic device.

| | Rated capacity | Voltage | Total charge | Weight | Quality factor |
|---|---|---|---|---|---|
| Battery type | (mAh) | (V) | (C) | (g) | (C.V.g⁻¹) |
| AA battery | 500-900 | 1.5 | 1800-3240 | 23.5 | 115-207 |
| NiMH (AA) | 1800-2800 | 1.5 | 6480-10080 | 23.5 | 414-643 |
| LiMn | 230 | 3.0 | 828 | 3.2 | 776 |
| Polymer solar | 1-10^{a} | 0.35-0.5^{a} | 720-7200^{b} | 0.034^{c} | 3705-105900 |
| cell | (mA · cm⁻²) | | | | |
| P3CT: ZnO | 0.5^{a,d} | 0.3^{d} | 360^{e} | 0.042^{f} | 2570 |
| | (mA · cm⁻²) | | | | |

^{a}AM1.5G spectrum and 1000 W · m⁻² incident light intensity operating that the maximum power point.
^{b}Assuming an operational lifetime of 100 hours.
^{c}Using the actual weight per square centimetre of active area for a processed device on a 200 μm thick substrate with a density i 1 g · cm⁻³.
^{d}The current and voltage at the maximum power point.
^{e}Using the typical current generated for these devices during 100 hours of operation.
^{f}Weight of this device prepared on a 200 μm thick PET substrate.

The battery relies on energy stored chemically and when energy is drawn from a battery, chemical reactions inside the battery are the source of the electrical energy. This process continues until the chemicals available inside the battery has been consumed and this therefore places a limit on the capacity of the battery. The energy output (depending on the battery type) is typically quite constant throughout the service life of the battery. In this respect a photovoltaic device differs as it will operate only as long as it is illuminated. However, polymer photovoltaics degrade and this means that they have a finite service life just like batteries. The lifetime of the polymer photovoltaic thus comes into play when wishing to compare the performance of the two technologies. In order to find the best means to compare the electrical performance of the two technologies hard physical factors such as the total charge that can be delivered (in coulombs), the energy at which this is available per unit charge (in volts) and the device weight (in grams) are good factors. There are further soft factors that do not readily enter a numerical equation such as flexibility and environmental friendliness. The comparison in the table is made based on the rated capacity in (mAh) for different battery technologies. The comparison with solar cells is made by taking the current density that these can deliver per square centimetre of processed device active area. The current densities that can be obtained with the state-of-the-art is in the range 1-10 mA.cm⁻² which implies that a considerable area of solar cell must be available to compete with the batteries in terms of the nominal current that the devices supplies. It has to be remembered that the incident light intensity will rarely approach AM1.5G and 1000 W.m⁻² and therefore a polymer solar cell area of the order of 100 cm² would be needed to efficiently replace a type AA battery under variable lighting conditions. A challenge for the designer is thus to encompass all the possible lighting environments that the application may experience.

The output voltage of the polymer solar cell is given by the maximum power point of the device assuming that the polymer solar cell is operated for maximum power extraction (while this may not be the case). The output voltage at the maximum power point changes a little depending on the incident light intensity and the current that the polymer solar cell delivers is directly proportional to the incident light intensity. The values used for current and voltage in the table are thus neither the short circuit current (I_{sc}) nor the open circuit voltage (V_{oc}) but the corresponding values at the maximum power point.

The values shown in the table are crude figures meant to give an overview and detailed analysis is needed in specific cases. The data however underline that the polymer solar cells offer distinct advantages by a significant margin in terms of performance when using the merit factor that takes the total charge generated, the voltage and the device weight into account. Based on the data in the table it would appear that polymer solar cells with the current state-of-the-art outperform traditional batteries by a factor of 10-100. The specific technology presented here outperforms traditional batteries with a factor of 10-25 and are better in performance by a factor of 4-5 than LiMn batteries designed for applications requiring a low quiescent current.

With respect to the soft factors the advantages of polymer are obvious as issues such as flexibility, allowing for design freedom, and the environmental benefits of having biodegradable materials that solve concerns of disposal in nature. A final possibility is to combine the solar cell technology with flexible batteries or a supercapacitor thus combining the best of both technologies (autonomy in light and energy storage for use in the dark).

### Example 10

### Device Testing of Tandem Cell of the Structure Glass-ITO-ZnO-P3CT/ZnO-PEDOT-ZnO-P3CTTP/ZnO-PEDOT-Ag

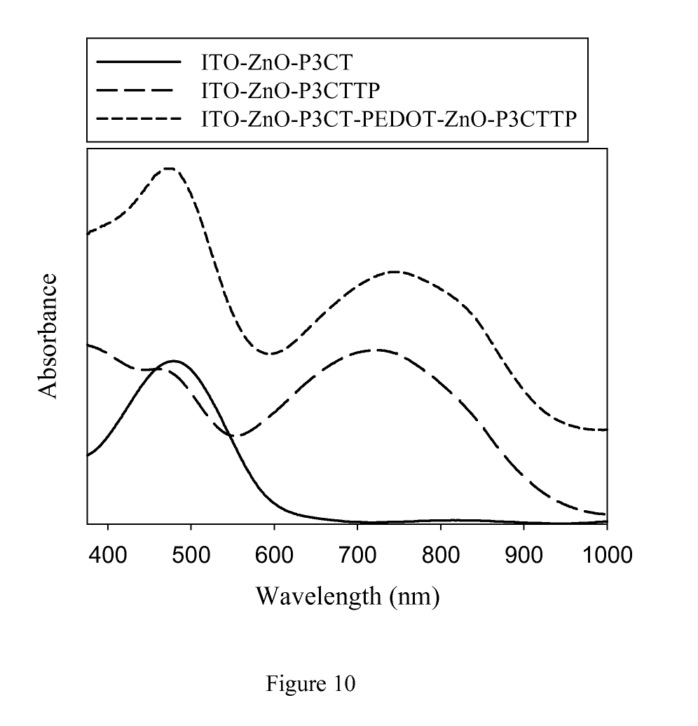

FIG. 10 shows the absorbance of the P3CT layer and the P3CTTP layer individually and the absorbance of the entire tandem cell stack.

Under illumination with 1 sun (1000 W m⁻², AM1.5G, 72° C., 30% relative humidity) the tandem cells typically gave an open circuit voltage of 0.6-0.9V and a short circuit current of 0.6-1.5 mA cm⁻². The fill factor was 0.29-0.35 and the best power conversion efficiencies were in the range 0.1-0.5%.

1. A method of forming a conducting polymer based photovoltaic device comprising the steps of:
(a) providing a transparent first electrode;
(b) providing the transparent first electrode with a layer of metal oxide nanoparticles, wherein the metal oxide is selected from the group consisting of: TiO₂, TiOₓ and ZnO;
(c) providing the layer of metal oxide nanoparticles with a bulk heterojunction layer comprising metal oxide nanoparticles and a hole conducting polymer containing thermocleavable groups, wherein the metal oxide is selected from the group consisting of: TiO₂, TiOₓ, CeO₂, Nb₂O₅ and ZnO;
(d) heating the bulk heterojunction layer to cleave the thermally cleavable groups to produce an insoluble hole containing polymer;
(e) providing the bulk heterojunction layer with a hole transporting layer; and
(f) providing the hole transporting layer with a second electrode.

2. The method according to claim 1, comprising the further steps of:
(g) connecting the photovoltaic device to a power consuming device; and
(h) exposing the photovoltaic device to light;
wherein the photovoltaic device is exposed to the ambient atmosphere and is not protected from oxygen in use.

3. The method according to claim 1, wherein the photovoltaic device is a solar cell.

4. The method according to claim 1, wherein the group of steps (b), (c), (d) and (e) are performed more than once between steps (a) and (f).

5. The method according to claim 1, wherein the transparent first electrode is provided on a transparent substrate.

6. The method according to claim 1, wherein the metal oxide nanoparticle layer is formed by application of a layer of a solution of metal oxide nanoparticles to the transparent electrode layer.

7. The method according to claim 1, wherein the hole conducting polymer is a polythiophene derivative.

8. The method according to claim 7, wherein the thermally-cleavable groups are the alkyl groups of an ester.

9. The method according to claim 1, wherein the bulk heterojunction layer is provided on the metal oxide layer by coating a solution of the metal oxide nanoparticles and hole conducting polymer onto the metal oxide layer followed by removal of the solvent.

10. The method according to claim 1, wherein step (d) is carried out using a laser in the wavelength range 475-532 nm.

11. The method according to claim 1, wherein the second electrode comprises a highly conductive layer that may distribute charge over the whole of its surface.

12. The method according to claim 11, wherein the highly conductive layer comprises silver.

13. The method according to claim 1, wherein the transparent electrode is formed from indium tin oxide.

14. The method according to claim 1, comprising the additional step of maturing the device in the dark before use.

15. (canceled)

16. A conducting polymer based photovoltaic device comprising the following layers:
(a) a transparent first electrode;
(b) a metal oxide nanoparticle layer, wherein the metal oxide is selected from the group consisting of: TiO₂, TiOₓ and ZnO;
(c) a bulk heterojunction layer comprising metal oxide nanoparticles and a hole conducting polymer which has been thermally treated to decrease its solubility, wherein the metal oxide is selected from the group consisting of: TiO₂, TiOₓ, ZnO, CeO₂ and Nb₂O₅;
(d) a hole transporting layer; and
(e) a second electrode.

17. A device according to claim 16, comprising no layers or coatings that exclude oxygen from contact with the bulk heterojunction layer while the device is in use.

18. A device according to claim 16, further comprising a UV filter.

19. A device according to claim 16, comprising more than one set of the layers (b), (c) and (d) between electrodes (a) and (e).

20. A compound having the formula:

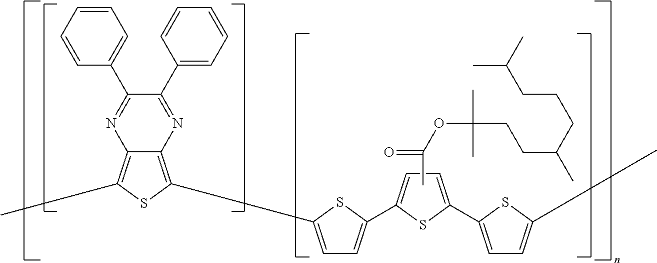

21. A compound having the formula:

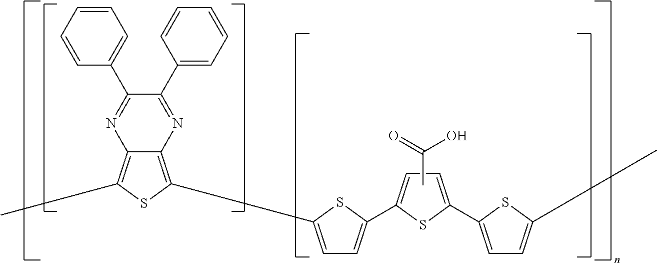

22. (canceled)

23. A method of forming the compound of claim 21 by thermal cleavage at 210° C. of a compound having the formula at 210° C.

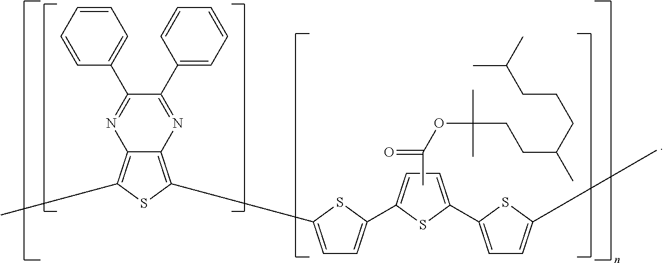

24. A method of forming poly(thiophene-co-diphenylthienopyrazine) (PTTP) having the formula: 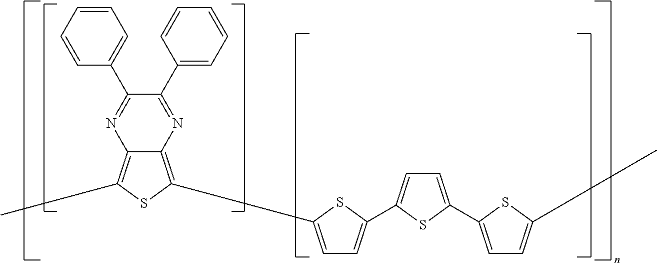
by thermal cleavage of the either of the compound of claim 20 at 310° C.

25. (canceled)

26. A method of making a polymer photovoltaic device according to claim 1, wherein the metal oxide layer, bulk heterojunction layer, hole transport layer and second electrode layer are all formed by screen printing.

27. A method according to claim 26, wherein the metal oxide layer and the bulk heterojunction layer are screen printed as solutions in a thermocleavable solvent.

28. A photovoltaic device comprising a compound according to claim 20.

29. A photovoltaic device comprising a compound according to claim 21.

30. A method of forming poly(thiophene-co-diphenylthienopyrazine) (PTTP) having the formula: 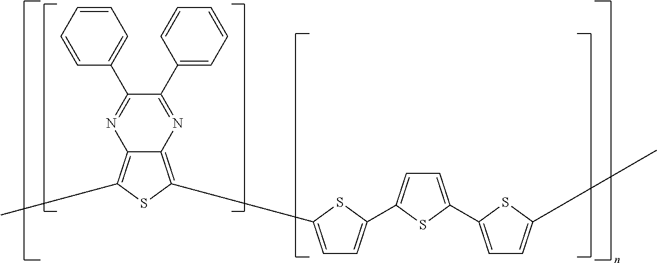
by thermal cleavage of the compound of claim 21 at 310° C.

31. A photovoltaic device comprising poly(thiophene-co-diphenylthienopyrazine) (PTTP).
